(19) United States
(12) Patent Application Publication
(10) Pub. No.: US 2019/0235014 A1
(43) Pub. Date: Aug. 1, 2019

(54) TEST SOCKET HEATING MODULE AND DEVICE TEST APPARATUS HAVING SAME

(71) Applicant: DAE SUNG ENGINEERING CO., LTD., Hwaseong-si (KR)

(72) Inventors: Wang Ki LEE, Yongin-si (KR); Dong Shin Kim, Hwaseong-si (KR)

(21) Appl. No.: 16/220,467

(22) Filed: Dec. 14, 2018

(30) Foreign Application Priority Data
Jan. 30, 2018 (KR) 10-2018-0011440

(51) Int. Cl. G01R 31/26; G01R 31/27; G01N 25/72; G01R 1/04

(52) U.S. Cl. CPC G01R 31/2601; G01R 31/2642; G01R 1/0416; G01R 31/27; G01N 25/72; G01R 31/2644

(57) ABSTRACT

The present invention relates to a test socket heating module and a device test apparatus including the same, and more particularly, to a test socket heating module for performing a high-temperature test on a device, and a device test apparatus including the same. The present invention discloses a test socket heating module (200) including: a support plate (210) installed to be spaced apart a distance from a bottom surface of a test board (100) which is provided with one or more test sockets (20) for performing a test on a device (10) mounted on the test sockets; and one or more heater units (220) which are coupled to the support plate (210) between the test board (100) and the support plate (210), and heat the corresponding test sockets (20), respectively.

### TECHNICAL FIELD

The present invention relates to a test socket heating module and a device test apparatus including the same, and more particularly, to a test socket heating module for performing a high-temperature test on a device, and a device test apparatus including the same.

### BACKGROUND ART

Semiconductor devices (hereinafter referred to as “devices”) undergo various tests, such as tests on electrical characteristics and reliability against heat, or pressure, after completing a packaging process.

For example, semiconductors undergo a high-temperature test regarding whether to normally operate under a high-temperature environment, and here, providing a constant temperature to the devices serves as very important factor to enhance the reliability of the high-temperature test.

However, in case of conventional high-temperature tests, a method in which a device inserted into a socket of an ATE board is heated by using a heater-embedded handler, and thus, there are problems in that substantial heat loss of a heater occurs through the handler, quick heat transfer is not quickly achieved, and it is difficult to supply a constant temperature to the device.

### SUMMARY

The purpose of the present invention is to provide a test socket heating module capable of improving the reliability of a test on a device by preventing heat losses and heating the device at a constant temperature.

The present invention discloses a test socket heating module (200) including: a support plate (210) installed to be spaced apart a distance from a bottom surface of a test board (100) which is provided with one or more test sockets (20) for performing a test on a device (10) mounted on the test sockets; and one or more heater units (220) which are coupled to the support plate (210) between the test board (100) and the support plate (210), and configured to heat the corresponding test sockets (20), respectively.

The heater unit (220) may include: a heat insulation block (222) installed on the upper surface of the support plate (210); a heating unit (224) disposed on the upper surface of the heat insulation block (222); and a heat transfer unit (226) which is disposed on the upper surface of the heating unit (224) and is in surface contact with the bottom surface of the test board (100) in order to transfer heat generated from the heating unit (224) to the test socket (20).

The heating unit (224) may include: a ceramic body (310); and a heating body (320) which is embedded in the ceramic body (310) and generates heat by current applied thereto from an external power supply.

The ceramic body (310) may include a first ceramic body (312) and a second ceramic body (314) which are coupled with the heating body (320) therebetween, and have a pair of parallel plate surfaces.

The heating body (320) may include a heat wire printed on any one of the first ceramic body (312) and the second ceramic body (314).

The heating unit (224) may further include a pair of electrodes (330) provided to at least one of the first ceramic body (312) and the second ceramic body (314).

The test socket heating module (200) may further include a control unit which controls the heating unit (224) not to operate when the capacitance of the pair of the pair of electrodes (330) is out of a preset reference range.

The test socket heating module (200) may further include a temperature sensor (230) installed between the heat insulation block (222) and the heating unit (224) in order to measure a temperature of the heating unit (224).

The test socket heating module (200) may further include a control unit which controls power applied to the heating body (320) on the basis of a temperature value measured from the temperature sensor 230.

In another aspect, the present invention discloses a device test apparatus (1) including: a test board (100) provided with one or more test sockets (20) on each of which a device (10) is mounted and a test on the device (10) is performed; and a test socket heating module (200), which heats the test socket (20) from the bottom surface of the test board (100).

A test socket heating module and a device test apparatus including the same according to the present invention have merits in that the test socket heating module is installed on the bottom surface of a test board provided with a test socket, on which a device is mounted, and thus, heat generated from the test socket heating module can be quickly transferred to a test socket, and a high-temperature test can be performed regardless of heat losses of a heater provided in a handler.

Specifically, in the test socket heating module and the device test apparatus including the same according to the present invention, the temperature of the test socket heating module installed on the bottom surface of the test board is controlled by a control unit, and thus, there is a merit in that the device can be heated at a preset constant temperature to thereby remarkably improve the reliability of a high-temperature test.

In addition, in the test socket heating module and the device test apparatus including the same according to the present invention, a pair of electrodes whose capacitance can be measured are disposed on a heating unit of the test socket heating module, and thus, whether to operate the heating unit can be determined by determining whether the heating unit is compatible with respect to the capacitance, and there is a merit in that using an incompatible heating unit for the test socket heating module can be effectively prevented.

### BRIEF DESCRIPTION OF THE DRAWINGS

Exemplary embodiments can be understood in more detail from the following description taken in conjunction with the accompanying drawings, in which:

FIG. 1 is a front view illustrating a device test apparatus according to an embodiment of the present invention;

FIG. 2 is a perspective view illustrating a test socket heating module of the device test apparatus of FIG. 1;

FIG. 3 is a plan view illustrating the test socket heating module of FIG. 2;

FIG. 4 is an exploded perspective view illustrating the test socket heating module of FIG. 2;

FIG. 5 is an exploded perspective view illustrating a portion of the test socket heating module of FIG. 4; and

FIG. 6 is a cross-sectional view taken along line II-II of FIG. 5.

### DETAILED DESCRIPTION OF EMBODIMENTS

Hereinafter, a test socket heating module and a device test apparatus will be described below with reference to the accompanying drawings.

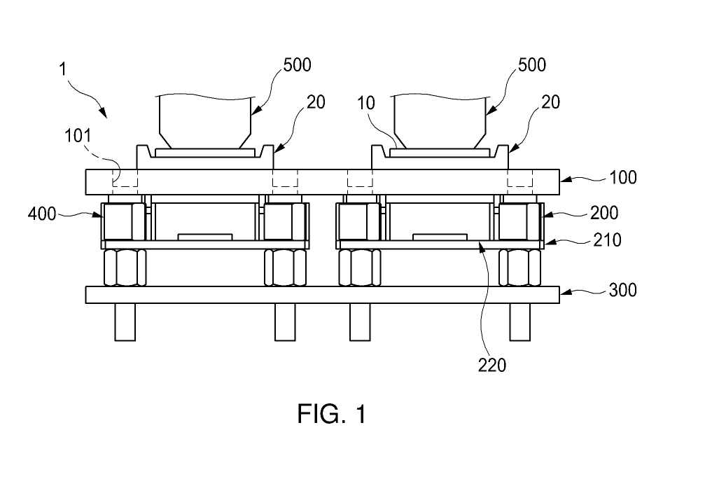

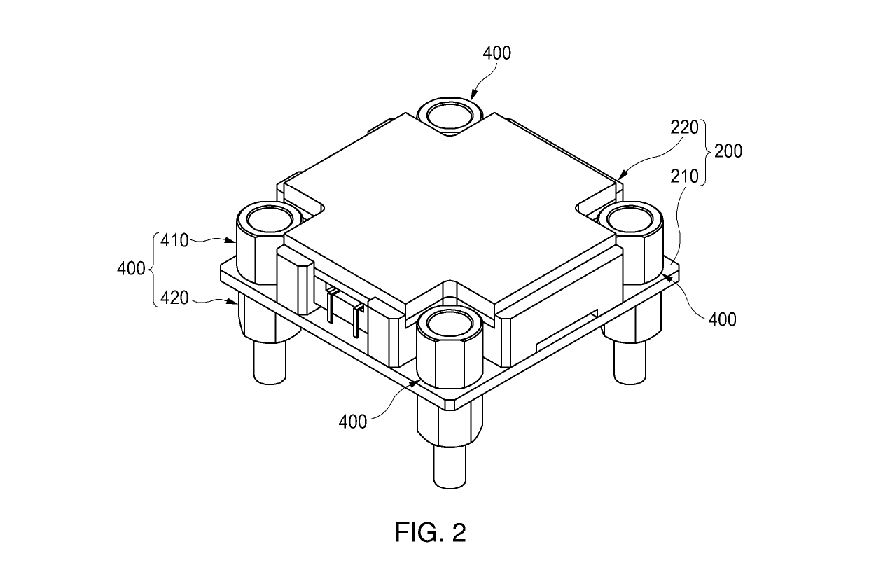

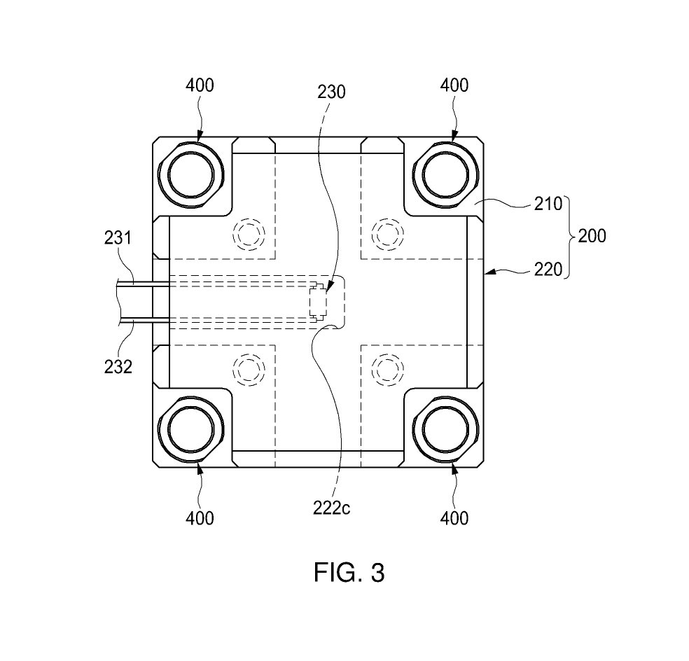

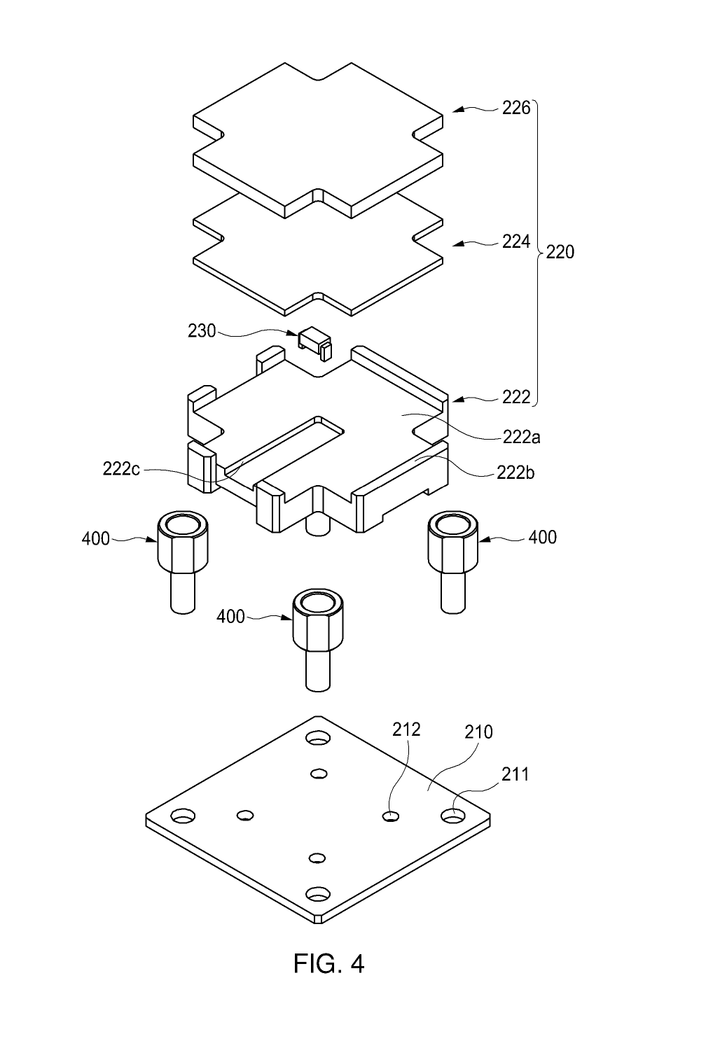

A device test apparatus 1 according to the present invention includes, as shown FIGS. 1 to 6: a test board 100 provided with one or more test sockets on each of which a device 10 is mounted and a test on the device is performed; and a test socket heating module 200 which heats the test socket 20 from the bottom surface of the test board 100.

Here, the device 10 may be a semiconductor device completely undergone a packaging process, for example, may be a ball grid array (BGA) device having a plurality of ball terminals on the bottom surface thereof.

The test board 100 is a component having an upper surface on which one or more test sockets 20 for performing a test on the vice 10 mounted on the test sockets are installed, and may be variously configured.

The test board 100 is a board on which devices 10 to be tested are mounted, and various circuit components may be mounted.

The test socket 20 is a component, on which the device 10 to be tested is mounted and which performs a test on the device 10 and may be variously configured.

The test socket 20 may be disposed in various ways, such as being disposed in double rows at regular intervals on the test board 100.

In addition, the test socket 20 may be provided with a plurality of contact pins (not shown) installed therein for applying power and signals corresponding to a plurality of ball terminals provided on the bottom surface of the device 10.

The test socket 20 may have any configuration as long as a plurality of contact pins are installed thereon including the structure disclosed in Korea registered utility model No. 20-0463425 or the like.

The test board 100 according to the present invention corresponds to a general component applied to conventional automatic test equipment (ATE), and thus, a detailed description thereon will not be provided for clarifying the subject matters of the present invention.

Meanwhile, as shown in FIG. 1, in a conventional device test apparatus 1, the device 10 mounted on the test socket 20 by the handler 500 is heated by a heater (not shown) provided to the handler 500 and a high-temperature test is performed on the device.

Here, the device 10 is heated to approximately 85° C. in order to obtain reliable test results, and the heating temperature of the device is required to be maintained for a reliable device test.

However, in the heater provided to the handler 500, a significant heat loss occurs through the handler 500, and thus, the thermal efficiency is very low when heat is applied to the test socket 20 and it is difficult to control the test socket 20 to maintain a preset constant temperature. Therefore, there is a problem in that reliability of tests is remarkably degraded.

Accordingly, the device test apparatus 1 according to the present invention is further provided with a test socket heating module 200 which heats the test socket 20 installed on the upper surface of the test board 100 from the bottom surface of the test board 100.

The test socket heating module 200 is a component which heats the test socket 20 installed on the upper surface of the test board 100 from the bottom surface of the test board 100, and may be variously configured.

For example, the test socket heating module 200 may include: a support plate 210 installed to be spaced apart a distance from the bottom surface of the test board 100 which is provided with one or more test sockets 20 for performing a test on a device 10 mounted on the test sockets 20; and one or more heater units 220 which are coupled to the support plate 210 between the test board 100 and the support plate 210, and heat the corresponding test sockets 20, respectively.

The support plate 210 is a sheet-like plate which is installed to be spaced apart a distance from the bottom surface of the test board 100, and may be variously configured. For example, the support plate 210 may be configured from a printed circuit board (PCB). Specifically, the support plate 210 may be a PCB board made of an FR4 material.

When the support plate 210 is configured form an FR4 PCB board, there are merits of low costs, excellent heat insulation, and low conductivity.

In addition, the support plate 210 serves a supporting function for the heater unit 220 to be described later, and of course, in order to control the operation of the heater unit 220, the support plate 220 may serve as a circuit component electrically connected to the heater unit 220 or a control unit to be described later.

The support plate 210 may have, but not limited to, a rectangular planar shape.

One or a plurality of heater units 220 to be described later may be disposed on the upper surface of the support plate 210.

In addition, the support plate 210 is favorably installed parallel to the bottom surface of the test board 100, and as long as fixedly installed to the bottom surface of the test board 100, the support plate may be coupled to the test board 100 through various methods.

For example, the support plate 210, as shown in FIGS. 1 to 4, may be coupled to the bottom surface of the test board 100 through one or more fastening members 400. At this point, the support plate 210 and the test board 100 may be provided with fastening holes 211 and 101, through which the fastening members 400 pass to be fixed.

The fastening members 400 are mounters which couple the test board 100 and the support plate 210 while being spaced apart a distance from each other, and may be various components, such as bolts or nuts.

In an embodiment, the fastening members 400 may include: first fastening members 410 which pass through the test board 100 and fixed; and second fastening members 420 which pass through the support plate 210 and coupled and fixed to the first fastening members 410.

In addition, favorably, in order to improve the close contact between the test board 100 and the test socket heating module 200, the plurality of fastening members 400 are installed respectively along the boundaries of the test sockets.

For example, the fastening members 400 may be arranged in a lattice pattern on the test board 100 and the support plate 210 so that the test socket heating module 200 is positioned at the inside surrounded by the plurality of fastening members 400.

In an embodiment, when the support plate 210 is formed in a rectangular planar shape and coupled to one heater unit 220, the fastening members 400 may be respectively installed at the positions corresponding to the vertices of the rectangle of the support plate 210.

The heater unit 220 is coupled to the support plate 210 between the test board 100 and the support plate 210, and heats the corresponding test socket 20, and may be variously configured.

In the present invention, in order to minimize heat losses, the heater unit 220 may be arranged at a position vertically overlapping the test socket 20 on the bottom surface of the test board 100.

In addition, of course, the heater unit 220 can be formed in various planar shapes as long as the heater unit can uniformly heat the corresponding test socket 210.

That is, the heater unit 220 may have various planar shapes such as circles, polygons or rings, as long as the heater unit 220 can avoid the interference with the fastening members 400 or other circuit components in regions which do not overlap the fastening members 400.

However, when it is assumed that the same power of the external power supply is supplied to the heater unit 220, there is a merit in that the larger the area of a portion at which the bottom surface of the test board 100 and the heater unit 220 are in surface contact with each other, the lower the heat density per unit area of a heat transfer unit 226 to be described later. Therefore, favorably, the heater unit 220 is configured to have a maximally large area within the range that does not overlap the fastening members 400.

For example, as shown in FIGS. 1 to 4, when the fastening members 400 are arranged in a lattice pattern on the support plate 210, in order to be in surface contact with the test board 100 as widely as possible, the heater unit 220 may be formed in a cross-type planar shape † in which vertex portions corresponding to the four fastening members 400 surrounding the heater unit 220 are removed.

The cross-shaped protruding heater unit 220 extending to four sides up to the spaces between the fastening members 400 has an area increased by at least 160% when compared to the case in which the heater unit 220 has a shape limited to the inside of the four fastening members 400 surrounding the heater unit 220. Thus, the heat density per unit area may be lowered as much, and accordingly, there is a merit in that heating and heat transfer may be more efficiently performed.

Meanwhile, the heater unit 220, as shown in FIGS. 1 to 6, may include: a heat insulation block 222 installed on the upper surface of the support plate 210; a heating unit 224 disposed on the upper surface of the heat insulation block 222; and a heat transfer unit 226 which is disposed on the upper surface of the heating unit 224 and is in surface contact with the bottom surface of the test board 100 in order to transfer heat generated from the heating unit 224 to the test socket 20.

The heat insulation block 222 is a component which is installed on the upper surface of the support plate 210 to prevent the heat generated from the heating unit 224 from being transferred to the support plate 210, and may have various shapes and materials.

For example, the heat insulation block 222 may be, but not limited to, a heater block made of a polyamide-imide material (e.g., Toron) having excellent resistance against friction, heat and chemicals.

The heat insulation block 222 may be fixedly coupled to the support plate 210 at a position vertically overlapping the corresponding test socket 20 on the upper surface of the support plate 210. Here, the support plate 210 may be provided with fastening holes 212 for being coupled to the heat insulation block 222 through a mounting member.

In addition, on the upper surface of the heat insulation block 222, a mounting region 222a is formed on which the heating unit 224 to be described later is mounted, and on the periphery of the mounting region 222a, protruding parts 222b protruding upward may be formed so as to stably maintain the position of the heating unit 224 and surround the side surface of the heating unit 224.

The heating unit 224 is a component which is disposed on the upper surface of the heat insulation block 222 and generates heat by current applied thereto from an external power supply through a terminal part 224a, and may be variously configured.

For example, the heating unit 224 may be a ceramic heater including hating wires having a preset pattern.

Specifically, the heating unit 224 may include: a ceramic body 310; and a heating body 320 which is embedded in the ceramic body 310 and generates heat by current applied thereto from an external power supply.

The ceramic body 310 is a ceramic plate having the heating body 320 embedded therein and may be formed in various planar shapes and thicknesses according to design, but favorably, the ceramic body is formed in a planar shape corresponding to the planar shape of the heat insulation block 222 described above.

For example, the ceramic body 310 may include a first ceramic body 312 and a second ceramic body 314 which are coupled to each other with the heating body 320 therebetween, and have a pair of parallel plate surfaces.

The first ceramic body 312 and the second ceramic body 314 are stacked along the stacking direction of the heater unit 220 and the heating body 320 may be embedded between the first ceramic body 312 and the second ceramic body 314.

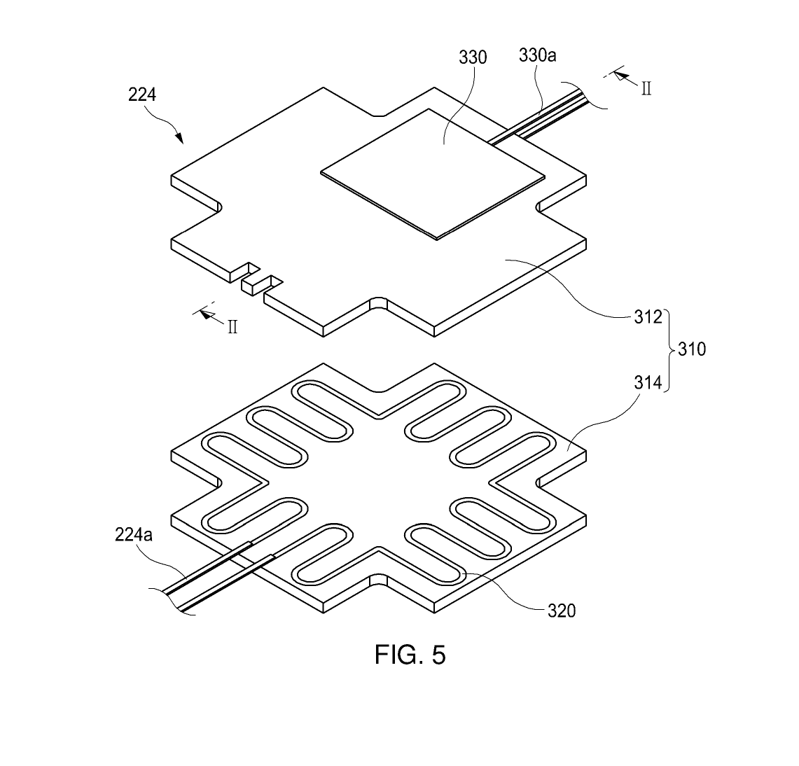

As shown in FIG. 5, the first ceramic body 312 and the second ceramic body 314 are plates which face each other and have a pair of plate surfaces, and favorably have the same planar shape so as to completely overlap each other when stacked and coupled.

The heating body 320 is a component which generates heat by current applied thereto from an external power supply through the terminal part 224a, may be variously configured, and may include, for example, a heat wire having a preset pattern.

In an embodiment, the heating body 320 may include a heat wire printed as a metal paste (for example, tungsten paste etc.) on any one of the first ceramic body 312 and the second ceramic body 314. Here, the heat wire may be printed on a coupling surface between the first ceramic body 312 and the second ceramic body 314.

Here, the heating unit 224 may further include a pair of electrodes 330 provided on at least one of the first ceramic body 312 and the second ceramic body 314.

For example, the pair of electrodes 330 may be provided on the pair of plate surfaces of the first ceramic body 312. Here, a heating body 320 may be formed on a plate surface of the second ceramic body 314.

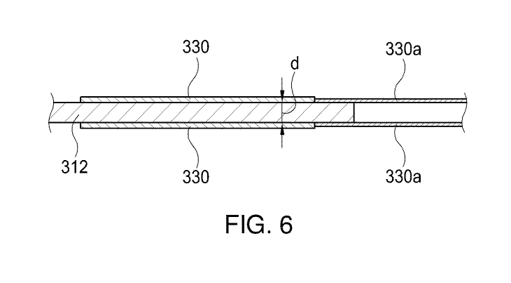

As shown in FIGS. 5 and 6, the plurality of electrodes 330 are formed in the same shape and size, and may form a distance between each other as much as the thickness (distance d between the pair of plate surfaces) of the first ceramic body 312. Here, the pair of electrodes 330 are members independent from the first ceramic body 312, and may be formed by being coupled to the first ceramic body 312 or being printed to the first ceramic body 312 by using a metal paste (for example, silver paste).

Accordingly, the pair of electrodes 330 may function as a capacitor. Here, the capacitance of the pair of electrodes 330 may be calculated according to the dielectric constant of the first ceramic body 312, the thickness of the first ceramic body 312, and the area of the electrodes, and the capacitance of the pair of the electrodes 330 may be measured through the connection terminal part 330a electrically connected to the control unit to be described later. The function of the pair of electrodes 330 will be described later together with the control unit.

The heat transfer unit 226 is component which is disposed on the upper surface of the heating unit 224 and transfers the heat generated from the heating unit 224 to the test socket 20, and may have various shapes and materials.

The heat transfer unit 226 may be installed on the bottom surface of the test board 100, and particularly, installed so as to be in surface contact with a region vertically overlapping the test socket.

For example, the heat transfer unit 226 may be a heat conduction gap pad which has a thermal conductivity of approximately 1.50 w/mK or greater and can operate at temperatures of approximately −50° C. to approximately 180° C.

In addition, the test socket heating module 200 may further include one or more temperature sensors 230 for measuring the temperature of the heating unit 224.

The temperature sensors 230 may be installed between the heat insulation block 222 and the heating unit 224 to measure the temperature of the heating unit 224.

Here, on the upper surface of the heat insulation block 222, a groove part 222c, which is formed from the central portion of the heat insulation block 222 to one side surface of the heat insulation block 222, may be formed in order to install the temperature sensor 230 and terminal wires 231 and 232 of the temperature sensor 230. The temperature sensor 230 may be installed in the groove part 222c and contact the heating unit 224.

The test socket heating module 200 including the above configuration may further include a control unit for controlling the operation of the test socket heating module 200.

When the capacitance of the pair of the pair of electrodes 330 provided to the ceramic body 310 is out of the preset reference range, the control unit may control the heating unit 224 so as not to operate.

When the capacitance of the pair of the pair of electrodes 330 provided to the ceramic body 310 is out of the preset reference range, the control unit classifies the corresponding heating unit 224 as a product incompatible to a reference and may control so as not to apply current to the heating unit 224.

That is, the control unit checks the capacitance of the pair of the electrodes 330 before operating the heating unit 224 and controls the heating unit 224 so as to operate only when the capacitance is not out of the preset reference range, and thus, only the heating unit 224 suitable for the test socket heating module 200 of the present invention is allowed to be used, and safe and stable operation of the heating unit 224 may be guaranteed.

In addition, the control unit may control the power (current value or voltage value) applied to the heating body 320 on the basis of the temperature value measured from the temperature sensor 230.

In addition, the control unit may apply a slight current to the heating unit 224 and thereby obtain, separately from the temperature sensor 230, the resistance value of the heating unit 224 (particularly, the heating body 320), and may calculate a temperature value of the heating body 320 through the relationship between the resistance value and the temperature value.

That is, the control unit according to the present invention controls the power applied to the heating body 320 on the basis of the temperature value calculated from the resistance value and the temperature value detected through the temperature sensor 230, and thus, there is a merit in that accurate temperature measurement, quick response, and stability can be guaranteed, and consequently, a constant and uniform temperature may be supplied to the test socket 20.

Specifically, the control unit may control the power applied to the heater unit 220 by comparing the preset set temperature and the measure temperature value (or temperature value calculated through the resistance value).

For example, when the temperature of the heater unit 220 reaches the preset set temperature, the control unit blocks the power applied to the heater unit 220, and when the temperature of the heater unit 220 is lowered than the preset set temperature, the power applied to the heater unit 220 may be increased.

In addition, the control unit may independently or integrally control the plurality of heater units 220 installed on the test board 100.

Meanwhile, the device test apparatus 1 may further include a sub board 300 installed to be spaced apart a distance from the bottom surface of the test board 100.

The sub board 300 is a board, on which peripheral components such as relay circuits for device test are installed, and may be variously configured.

The sub board 300 is generally installed with a preset gap from the test board 100 according to a design of the device test apparatus 1.

Here, the sub board 300 may be coupled to the bottom surface of the test socket heating module 200 through the fastening members 400.

The sub board 300 according to the present invention corresponds to a general component applied to conventional automatic test equipment (ATE), and thus, detailed descriptions thereon will not be provided for clarifying the subject matters of the present invention.

The above-disclosed subject matter merely describes some portions of preferred embodiments that can be implemented by the present invention. Therefore, as is well known, the scope of the invention shall not be construed as limited to the embodiments above, and technical ideas that share a base with the aforementioned technical idea of the present invention would all be included in the scope of the invention.

What is claimed is:

1. A test socket heating module (200) comprising:
a support plate (210) installed to be spaced apart a distance from a bottom surface of a test board (100) which is provided with one or more test sockets (20) for performing a test on a device (10) mounted on the test sockets (20); and
one or more heater units (220) which are coupled to the support plate (210) between the test board (100) and the support plate (210), and configured to heat the corresponding test sockets (20), respectively.

2. The test socket heating module (200) of claim 1, wherein the heater unit (220) comprises:
a heat insulation block (222) installed on the upper surface of the support plate (210);
a heating unit (224) disposed on the upper surface of the heat insulation block (222); and
a heat transfer unit (226) which is disposed on the upper surface of the heating unit (224) and is in surface contact with the bottom surface of the test board (100) in order to transfer heat generated from the heating unit (224) to the test socket (20).

3. The test socket heating module (200) of claim 2, wherein the heating unit (224) comprises:
a ceramic body (310); and
a heating body (320) which is embedded in the ceramic body (310) and generates heat by current applied thereto from an external power supply.

4. The test socket heating module (200) of claim 3, wherein the ceramic body (310) comprises a first ceramic body (312) and a second ceramic body (314) which are coupled with the heating body (320) therebetween, and have a pair of parallel plate surfaces.

5. The test socket heating module (200) of claim 4, wherein the heating body (320) comprises a heat wire printed on any one of the first ceramic body (312) and the second ceramic body (314).

6. The test socket heating module (200) of claim 4, wherein the heating unit (224) further comprises a pair of electrodes (330) provided on at least one of the first ceramic body (312) and the second ceramic body (314).

7. The test socket heating module (200) of claim 6, further comprising a control unit which controls the heating unit (224) not to operate when the capacitance of the pair of the pair of electrodes (330) provided to the ceramic body (200) is out of a preset reference range.

8. The test socket heating module (200) of claim 3, further comprising a temperature sensor (230) installed between the heat insulation block (222) and the heating unit (224) in order to measure a temperature of the heating unit (224).

9. The test socket heating module (200) of claim 8, further comprising a control unit which controls power applied to the heating body (320) on the basis of a temperature value measured from the temperature sensor (230).

10. A device test apparatus (1) comprising:
a test board (100) provided with one or more test sockets (20) on each of which a device (10) is mounted and a test on the device (10) is performed; and
a test socket heating module (200), which heats the test socket (20) from the bottom surface of the test board (100), as claimed in claim 1.
